(19) United States
(12) Patent Application Publication
(10) Pub. No.: US 2009/0263668 A1
(43) Pub. Date: Oct. 22, 2009

(54) DURABLE COATING OF AN OLIGOMER AND METHODS OF APPLYING

(75) Inventors: Moses M. DAVID, Woodbury, MN (US); Gregory D. Clark, Silver Spring, MD (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 12/424,806

(22) Filed: Apr. 16, 2009

Related U.S. Application Data
(60) Provisional application No. 61/046,506, filed on Apr. 21, 2008.

(51) Int. Cl. B32B 9/04; C08G 77/60; C08G 77/04; C08G 77/20; C08G 77/24; C08G 61/12; B05D 3/14; B32B 15/04; C23C 14/34

(52) U.S. Cl. 428/447; 528/35; 528/10; 528/32; 528/42; 528/397; 427/562; 428/411.1; 428/457; 428/689; 204/192.12

(57) ABSTRACT

A plasma cross-linked surface coating of an oligomer has resulted in a low friction surface coating that is also highly durable. The coated device comprises a metal substrate and a plasma cross-linked coating of an oligomer having a molecular weight less than 10,000, and in one embodiment a molecular weights between 1000 and 10,000.

### CROSS REFERENCE TO RELATED APPLICATION

This application claims the benefit of U.S. Provisional Patent Application No. 61/046,506, filed Apr. 21, 2008, the disclosure of which is incorporated by reference herein in its entirety.

### BACKGROUND

The present invention relates to a durable coating of an oligomer and a method for applying the coating to a substrate. In particular, the present invention relates to a cross-linked coating of an oligomer deposited onto a substrate using plasma-enhanced chemical vapor deposition (PECVD).

There are a variety of surface coatings that can be applied to metal substrates. Different coating can impart different features. For example, metal substrates can be coated to prevent corrosion of the metal. Coatings can be applied to increase the durability of the metal substrate, therefore extending the useful life of the metal substrate. Further, coatings exist that can create a low friction surface that have non-stick and easy-to-clean properties. Generally, coatings that create a non-stick surface have very limited resistance to abrasion and are therefore not very durable. An example would be PTFE treated cooking ware. Such articles are noted to provide easy-to-clean surfaces, but can be easily damaged.

Cutting applications presents unique challenges for coated articles. Generally, cutting tools are repeatedly used under conditions of high shear forces. These shear forces will tend to degrade, chip, flake, or otherwise destroy many types of coatings. Further, thick or very rough coatings can adversely impact the forces required to pass the cutting article through the material being cut.

### SUMMARY

Cutting tools, like cutting blades, are used repeatedly under conditions of high shear forces. It would be desirable to have a coating applied to the cutting tool that creates a highly durable surface that is resistant to abrasion. Further, a low friction surface coating on a cutting tool would reduce the force required to cut through a substrate and make for a surface that is easier to clean. A plasma cross-linked surface coating of an oligomer has resulted in a low friction surface coating that is also highly durable.

In one embodiment, a coated device comprises a metal substrate and a plasma cross-linked coating of an oligomer having a molecular weight less than 10,000, and in one embodiment a molecular weights between 1000 and 10,000.

In another embodiment, a cutting device comprises a metal substrate, a tie layer coated on the metal substrate, and a plasma cross-linked coating of an oligomer on the tie layer. The oligomer has a molecular weight between 1000 and 10,000.

In one embodiment, a method of coating comprises providing a metal substrate on an electrode in a chamber, providing a power supply to the electrode, introducing an oligomer into the chamber, activating the power supply to create a plasma of the oligomer within the chamber, depositing the oligomer on the metal substrate.

In another embodiment, a method of coating comprises providing a substrate on an electrode in a chamber, providing a power supply to the electrode, introducing an oligomer into the chamber, activating the power supply to create a plasma consisting of the oligomer within the chamber, depositing the oligomer on the substrate.

In another embodiment, a method of coating comprises providing a substrate on an electrode in a chamber, providing a power supply to the electrode, introducing an oligomer into the chamber, pulsing the power supply to create a plasma, depositing the oligomer on the substrate.

### BRIEF DESCRIPTION OF THE DRAWINGS

FIG. 1 shows a cross-sectional view of one embodiment of a coated substrate.

FIG. 2 shows a plasma deposition apparatus.

While the above-identified drawings and figures set forth embodiments of the invention, other embodiments are also contemplated, as noted in the discussion. In all cases, this disclosure presents the invention by way of representation and not limitation. It should be understood that numerous other modifications and embodiments can be devised by those skilled in the art, which fall within the scope and spirit of this invention.

The figures may not be drawn to scale.

### DETAILED DESCRIPTION

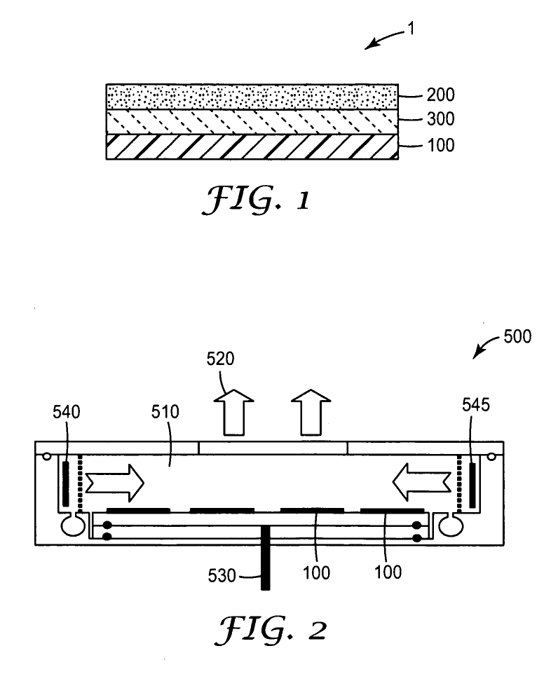

FIG. 1 shows a cross-sectional view of one embodiment of a coated article 1. A substrate 100 includes a plasma cross-linked coating 200 of an oligomer. Optionally, the substrate 100 may include a variety of surface treatments to enhance the adhesion between the substrate 100 and the plasma cross-linked coating 200. In one embodiment, one surface treatment may be to include an intermediate tie layer 300 to enhance the adhesion between the substrate 100 and the plasma cross-linked coating 200.

The substrate 100 can be a variety of different materials depending on the desired application for the coated substrate 100. In one embodiment, the substrate 100 is a metal material such as, but not limited to, steel, stainless steel, copper, brass, bronze, platinum, gold, silver, metal alloys. In another embodiment, the substrate 100 may be ceramics, glasses, or plastics. The substrate 100 itself may include a coating, such as a metal, prior to application of the plasma cross-linked coating 200.

The coating 200 may be a continuous coated over the entire surface of the substrate 100. In another embodiment, portions of the substrate 100 can be masked such that the coating 200 covers only predetermined portions of the substrate 100.

The coated article 1 may be used as a cutting tool, or in particular as a cutting blade. For example, the cutting blade may be a straight-edge blade, razor blade, scissors blade, knife, rotary blade any of which may include any variety of shapes and configurations to the cutting edge of the blade. For example, the cutting edge may be single or double beveled, linear, curved, or serrated.

The coated article 1 may also be used for other applications where a durable coating of a low friction material on a surface is desirable. For example, metal tools such as drill bits, non-stick cookware, saw blades, shaving razor blades, airplane wings, or hard disc drive metal components for corrosion protection.

An oligomer is used to create the plasma cross-linked coating 200. The oligomer may be in liquid or in solid form prior to coating. So that the oligomer is not too volatile, typically the oligomer has a molecular weight greater than 1000. Also, the oligomer typically has a molecular weight less than 10,000. An oligomer with a molecular weight greater than 10,000 typically may be too non-volatile, causing droplets to form during coating. In one embodiment, the oligomer has a molecular weight greater than 3000 and less than 7000. In another embodiment, the oligomer has a molecular weight greater than 3500 and less than 5500.

Typically, the oligomer has the properties of providing a low-friction surface coating. Suitable oligomers include silicone-containing hydrocarbons, reactive silicone containing trialkoxysilanes, aromatic and aliphatic hydrocarbons, fluorochemicals and combinations thereof. For examples, suitable resins include, but are not limited to, dimethylsilicone, hydrocarbon based polyether, fluorochemical polyether, and fluorosilicone.

Plasma polymerized thin films constitute a separate class of material from conventional polymers. In plasma polymers, the polymerization is random, the degree of cross-linking is extremely high, and the resulting polymer film is very different from the corresponding “conventional” polymer film. Thus, plasma polymers are considered by those skilled in the art to be a uniquely different class of materials. A surprising result was found in the present invention that if the plasma polymerized species constitutes an oligomer, then the resulting plasma cross-linked oligomer exhibits outstanding durability even under aggressive loading conditions that are encountered as in a cutting blade.

Through the process that will be described below, the oligomer undergoes a high degree of cross-linking to form coating 200. Generally, the coating 200 has a thickness from 0.1 to 3 microns.

An optional tie layer 300 may be included to promote adhesion between the substrate 100 and the plasma cross-linked coating 200. The tie layer 300 may be deposited either by physical vapor deposition (PVD) or by chemical vapor deposition (CVD). Suitable tie-layers are good carbide formers such as silicon carbide or silicon oxycarbide. Optionally, PVD deposited tie layers such as chromium, titanium, tungsten, molybdenum can be used. In one embodiment, the tie layer 300 is amorphous hydrogenated silicon carbide (a-Si:C:H) deposited by plasma decomposition of TMS (tetramethylsilane). Further, the tie layer 300 can be applied by plasma-enhanced vapor deposition prior to application of the plasma cross-linked coating 200. Typically, the tie layer has a thickness of greater than 0.01 micron. Typically, the tie layer has a thickness less than 1 micron. Following deposition of the tie layer, the surface of the tie layer 300 can be subject to further surface treatment to further promote adhesion between the substrate 100 and the coating 200.

It may be desirable to prepare the surface of the substrate 100 prior to application of the optional tie layer 300 or prior to application of the plasma cross-linked coating 200 to get better adhesion to the substrate 100. Surface preparation may include plasma treatment with argon, krypton, neon, nitrogen, oxygen, or other plasmas, chemical etching, electrodischarge machining (EDM), or sputter coating. These surface treatments can be applied to the surface of the substrate 100 or to the surface of a tie layer 300, if included.

FIG. 2 shows an apparatus 500 used to deposit the coating 200 of the oligomer by plasma-enhanced chemical vapor deposition (PECVD). The apparatus 500 includes a chamber 510 and is pumped by a turbomolecular pump 520, backed by a mechanical pump to draw down the pressure within the chamber 510. Powered electrodes 530 are located at the bottom of the chamber to support the substrate 100. The powered electrode 530 can be powered by a variety of sources, such as radio frequency or direct current.

Heating cloths 540, 545, typically graphite heating cloths, are located at the sides of the chamber. The heating cloths receive and hold the oligomer, when the oligomer is in a liquid state. AC voltage is connected to the cloth to raise the temperature of the heating cloths and ultimately achieve evaporation of the resin.

To use the apparatus 500, the substrate 100, which may already include a tie layer 300, is placed into the chamber 510 and placed on the powered electrode 530. The oligomer is injected by means of a syringe to the two heating cloths 540, 545. The chamber 510 is closed and pumped down to a base pressure. In one embodiment, the base pressure is lower than 10 mTorr. The AC power of the heating cloths 540, 545 is activated to heat the heating cloths 540, 545 and achieve evaporation of the oligomer. To carry out the deposition, the pressure within the chamber 510 is gradually reduced. In one embodiment, the pressure within the chamber 510 is reduced from 10 mTorr to about 2 mTorr. Generally, the deposition period is at least 10 seconds and generally less than 1 hour. In one embodiment, the deposition period is approximately 1 minute. After the deposition period, the AC power to the cloths 540, 545 and the power to the powered electrode 530 is turned off.

As discussed above, it may be advantageous to perform surface treatments to the substrate 100 to aid in adhering the plasma cross-linked coating 200. It is understood that the substrate 100 introduced into the chamber may include a tie layer 300. Then, following the process described above, the deposition is over the tie layer 300 coated substrate 100. Application of the tie layer 300 to the substrate 100 can be accomplished by plasma enhance chemical vapor deposition (PECVD). The PECVD application of the tie layer 300 could be carried out within the same chamber that will be used for applying the oligomer, or in a separate chamber.

Other surface treatments can be utilized as well. For example, one preferred surface treatment is ion bombardment. Ion bombardment can be used on the substrate to aid in adhesion of the tie layer (if included) or to aid in adhesion of the coating 200. Further, if a tie layer is included, then ion bombardment can be also used on the surface of the tie layer to aid in adhesion of the coating 200 to the tie layer 300.

Typically, the ion bombardment within the chamber is carried out and preferably continued during the introduction of the material used for the tie layer (if included) or during the introduction of the oligomer. Especially for the coating of the oligomer, it has been found that including only the oligomer within the chamber during the PECVD process results in a coating 200 having the best combination of a durable coating with low friction properties. Without being limited to any one particular theory, Applicant believes that because the oligomer is a much larger molecule, which in the plasma phase a more significant bombardment of the metal substrate by the oligomer takes place. When an additional species, such as argon, is present in the chamber, it reduces the overall amount of the oligomer also present. Therefore, less significant bombardment of the metal substrate takes place and the overall durability of the coating is less. By including only the oligomer within the chamber, the large molecule makes significant impacts with the metal substrate making for a much more durable coating.

The powered electrode 530 energizes the vapor in the chamber 510 to create the plasma. The plasma has charged carriers, which are energized while the powered electrode 530 is on. However, when the powered electrode 530 is off, the charged carriers quickly decay and the charge carrying species (electrons and ions) are attracted to the electrode and dissipate. It has been found that pulsing the power to the powered electrode 530 preserves the chemical makeup of the oligomer so that the plasma cross-linked coating of the oligomer imparts low friction properties to the substrate. In particular, the power to the powered electrode 530 is pulsed between intervals of off and on.

Without being limited to any one particular theory, Applicant believes that the high energy conditions of the plasma, cause either extensive fragmentation and/or degradation of the oligomer. Therefore, the oligomer may not maintain the desirable low friction properties. By reducing the power or eliminating the power during portions of the deposition time, the chemical makeup of the oligomer is preserved so that the coating includes low friction properties. However, because the plasma component is reduced, the resin undergoes less cross-linking, and therefore the hardness and durability of the coating 200 are also reduced. Therefore, a balance is achieved between durability of the coating 200 and low friction properties of the coating 200.

The duty cycle is the percent of the time that the power to the powered electrode 530 is on. The higher the duty cycle, the more the plasma phase tends to break up the oligomer molecule and therefore reduce the low friction properties of the plasma cross-linked coating 200. A duty cycle of 75% or less has resulted in a coating 200 maintaining a lower friction surface and good durability during cutting. Power supplies capable of pulsing the output power are needed to operate the plasma in a pulsed mode. These types of power supplies are available commercially from suppliers such as Advanced Energy of Fort Collins, Colo. and Seren of Vineland, N.J. Both the duty cycle and the frequency of the pulsing can be independently adjusted in these power supplies.

The plasma cross-linked coating 200 of the oligomer as applied using PECVD is both durable under conditions of high shear forces and has low-friction surface properties. Typically, it has been difficult to obtain a coating that has a low-friction surface that can also withstand high abrasion and especially high shear force conditions. Prior low-friction coating tended to flake off the substrate when subjection to high abrasion or high shear force conditions. The low-friction coating is particularly advantageous for cutting tools where a low-friction coating can provide a lower cutting force for passing through a surface being cut. Further, the coating process describe above can be carried out over a relative short deposition time.

As is described in more detail in the Examples below, the plasma cross-linked oligomer coating has a cutting force, as measured using the cutting force test method, of less than 7.0 lb_{f}/inch. In another embodiment, the plasma cross-linked oligomer coating has a cutting force of less than 6.0 lb_{f}/inch. In another embodiment, the plasma cross-linked oligomer coating has a cutting force of less than 5.0 lb_{f}/inch. In another embodiment, the plasma cross-linked oligomer coating has a cutting force of less than 4.0 lb_{f}/inch.

As is described in more detail in the Examples below, the plasma cross-linked oligomer coating has a cutting wear, as measured using the cutting wear test method, of greater than 50 cuts. In another embodiment, the plasma cross-linked oligomer coating has a cutting wear of greater than 300 cuts. In another embodiment, the plasma cross-linked oligomer coating has a cutting wear of greater than 100 cuts. In another embodiment, the plasma cross-linked oligomer coating has a cutting wear of greater than 400 cuts.

Although specific embodiments of this invention have been shown and described herein, it is understood that these embodiments are merely illustrative of the many possible specific arrangements that can be devised in application of the principles of the invention. Numerous and varied other arrangements can be devised in accordance with these principles by those of ordinary skill in the art without departing from the spirit and scope of the invention. Thus, the scope of the present invention should not be limited to the structures described in this application, but only by the structures described by the language of the claims and the equivalents of those structures.

### EXAMPLES

### Blade

The blade used for the coating applications was a GEM® stainless steel blade, part number 62-0167. Cutting force, as carried out using the below identified cutting force test method, of an uncoated blade is approximately 7.0 lb_{f}/inch and the uncoated blade showed wear marks following 160 cuts using the wear test method.

### Oligomers

DMS-T11: Polydimethylsiloxane trimethylsiloxy terminated, MW 1250, available from Gelest, Inc. of Morrisvile, Pa.

DMS-T15: Polydimethylsiloxane trimethylsiloxy terminated, MW 3780, available from Gelest, Inc. of Morrisvile, Pa.

DMS-T21: Polydimethylsiloxane trimethylsiloxy terminated, MW 5970, available from Gelest, Inc. of Morrisvile, Pa.

DMS-V03: Vinyl terminated polydimethylsiloxane, MW500, available from Gelest, Inc. of Morrisvile, Pa.

CN9800, Aliphatic Silicone Acrylate, MW 10,000, available from Sartomer Inc. of Exton, Pa.

FMS-131: Poly(3,3,trifluoropropylmethylsiloxane), MW 4600, available from Gelest, Inc. of Morrisvile, Pa.

Fromblin Y45: Poly(perfluoropropylether), MW 4100, available from Solvay Solexis, Inc. of West Deptford, N.J.

### Tie Layer

TMS (tetramethylsilane)-amorphous hydrogenated silicon carbide

### Coating Wear Test Method

An initial microscope picture of a blade is taken using a SPOT INSIGHT Color Camera, which was connected to an Olympus BH2 microscope. The picture focused on the blade edge portions of the hone and grind angle.

Each blade was placed in a hand held blade holder. Five layers of paper (EPSON plain bond paper, thickness per sheet 0.08 mm to 0.11 mm (0.003 to 0.004 inch), weight per reem 64 g/m² (17 lb) to 90 g/m² (24 lb) GDC) per set were assembled and each set of five sheets of paper was stapled together. The top sheet of each set contained 20 vertical columns number 1-20. The cuts were performed by positioning the blade left of center at the top of a numbered column. Each cut passed through the entire five layers of paper. After 100 cuts were performed, a new set of microscope pictures were taken of the same section of focus with respect to the initial pictures. The test continued until the adhesion, wear properties, and overall durability could be determined. In some cases where the coating was expected to degrade, pictures were taken before 100 cuts to closer approximate the point of failure.

### Cutting Force Test Method

A Sintech Instron 1/S available from Instron Worldwide of Norwood, Mass. was used to measure the cutting force required to pass a blade through a test material. The Instron machine was affixed with upper and lower clamps. The upper clamp was used to hold the blade in place over the testing region. The lower clamp was used to hold a flat metal platform in place. A level was used to ensure that the metal platform of the Instron machine was properly balanced. An elastomeric polyurethane bead (3M Bumpon™ protective products, available from 3M Company of St. Paul Minn.) resting on a 0.25 inch thick flat partition was positioned under the blade held by the upper clamp. The Instron machine was set to cut into the elastomeric bead to the depth of 0.1 inches and the cutting force was measured in pounds-force, (lb_{f}). At least five cutting force measurements were taken for each blade. Each test was performed over an unused region of the elastomeric bead.

### Sputter Coating of Tie Layer

Chromium layer was deposited from a chromium metal target using the magnetron sputtering process. Stainless steel razor blade substrates, first cleaned with isopropyl alcohol, were placed on a substrate holder set-up inside a vacuum chamber with a sputtering chromium target at 16 inches above the substrate holder. After the chamber was evacuated to 1×10⁻⁶ torr base pressure, argon sputter gas was admitted inside the chamber at a flow rate of 50 sccm (standard cubic centimeter per minute). The total pressure of the chamber was adjusted to 2 mTorr by adjusting the gate valve. Sputtering was initiated using a DC power supply at a constant power level of 0.05 kilowatts. The sputter duration was 15 min. The substrate was not heated and kept at room temperature. After 15 minutes sputter power was turned off and the vacuum chamber was back filled with argon gas to atmospheric pressure. The chamber was opened and the razor blades were turned to the second side where the described procedure was repeated for the second side.

### PECVD of Tie Layer

The cutting blade was clamped to the support rack and placed on the powered electrode in a plasma deposition system (Plasmatherm Model 3280). The chamber was closed and pumped down to a base pressure of 10 mTorr. Then, the metal blade was primed by argon plasma to promote adhesion of the tie layer to the metal blade. The argon flow rate was maintained at 250 sccm, pressure was 25 mTorr and the plasma was sustained at a radio frequency power of 2000 watts for 120 seconds. Immediately following the argon plasma priming, the TMS gas stream was initiated at a flow rate of 150 sccm, pressure of 25 mTorr and radio frequency power of 2000 watts for 10 seconds. The average thickness was 0.02 microns.

### PECVD of Oligomer

A chamber as shown in FIG. 2, which is constructed out of aluminum, was pumped by a turbomolecular pump (Pfeiffer, Model TPH510), which was backed by a mechanical pump (Edwards, Model E2M80). The substrate electrode was powered by a radio frequency power supply (Seren, Model R1001) operating at 13.56 MHz. The metal blade (which may or may not have included a tie layer) was placed on a powered electrode located horizontally at the bottom of the chamber. The oligomer was applied in equal quantities to the two graphite heating cloths by means of a syringe. The chamber was closed and pumped down to a base pressure of 0.1 mTorr. The blade was primed by argon plasma to promote adhesion. During the argon priming, the argon flow rate was maintained at 150 sccm, pressure was 10 mTorr, and the plasma was sustained at a radio frequency power of 1000 watts for 10 seconds. Then, unless otherwise noted, the argon gas was turned off and therefore was evacuated from the chamber.

Following the argon priming, the AC power (by means of a variable transformer available from Variac) applied to the graphite heating cloths was turned on with the plasma still active at 1000 watts power. The deposition of the oligomer was carried out for 1 minute. The pressure during the deposition decreased from 10 mTorr to about 2 mTorr during the 1 minute of deposition. After the 1 minute the power to the heating cloths and the radio frequency power was turned off.

Table 1 below shows Cutting Force data and Cutting Wear data for various oligomers coated to a metal blade by using the described plasma enhanced chemical vapor deposition process. For samples 1 and 2, the argon remained present during the oligomer deposition.

TABLE 1

| | | | | | Cutting | |
|---|---|---|---|---|---|---|
| Sample | | | Pressure | Power | Force | Wear |
| No. | Oligomer | Method | (mTorr) | (watts) | (lb_{f}/in) | Test |
| 1 | DMS-T11 | PECVD, | 14 | 1000 | 3.91 | 20 cuts |
| | | with | | | | |
| | | argon | | | | |
| 2 | DMS-T11 | PECVD, | 14 | 1000 | 4.05 | 4 cuts |
| | | with | | | | |
| | | argon | | | | |
| 3 | DMS-T11 | PECVD | 1-5 | 1000 | 5.16 | 100 cuts |
| 4 | DMS-T11 | PECVD | 1-5 | 1000 | 5.4 | 100 cuts |
| 5 | DMS-T11 | PECVD | 1-5 | 1000 | 5.78 | 80 cuts |
| 6 | DMS-V03 | PECVD | 1-5 | 1000 | 4.19 | 80 cuts |
| 7 | CN9800 | PECVD | 1-5 | 1000 | 3.73 | 80 cuts |

Table 2 below shows Cutting Force data and Cutting Wear data for various oligomers coated to a metal blade, where an intermediate tie layer is included. The tie layer and oligomer are coated using the specified coating method. The tie layer and oligomer are coated separately. For samples 1 to 7, the tie layer was deposited using PECVD followed by the oligomer being deposited using PECVD. In samples 8 and 9, the tie layer was deposited using sputter coating followed by the oligomer being deposited using PECVD. The high cuts for the cutting wear test in Table 2, as compared to the data in Table 1, shows that the oligomer has much better adhesion to the metal substrate and therefore much better durability.

TABLE 2

| | | | | Rf | | Cutting | Cutting |
|---|---|---|---|---|---|---|---|
| | | | Pressure | Power | | Force | Wear |
| Sample | Oligomer | Tie Layer | (mTorr) | (watts) | Method | (lb_{f}/in) | Test |
| 1 | DMS-T11 | TMS | 1-5 | 1000 | 2 step plasma | 5.04 | 300 |
| | | | | | | | cuts |
| 2 | DMS-T12 | TMS | 1-5 | 1000 | 2 step plasma | 8.1 | >300 |
| | | | | | | | cuts |
| 3 | DMS-T15 | TMS | 1-5 | 1000 | 2 step plasma | 5.35 | >300 |
| | | | | | | | cuts |
| 4 | DMS-T21 | TMS | 1-5 | 1000 | 2 step plasma | 5.24 | >300 |
| | | | | | | | cuts |
| 5 | FMS-131 | TMS | 1-5 | 1000 | 2 step plasma | 4.84 | >300 |
| | | | | | | | cuts |
| 7 | Fomblin | TMS | 1-5 | 1000 | 2 step plasma | 4.53 | >400 |
| | Y45 | | | | | | |
| 8 | DMS-T11 | Chromium | 1-5 | 1000 | Sputter/Plasma | 4.99 | >400 |
| | | | | | | | cuts |
| 9 | DMS-T11 | Chromium | 1-5 | 1000 | Sputter/Plasma | 4.66 | >400 |
| | | and TMS | | | | | cuts |

Table 3 below shows Cutting Force data and Cutting Wear data for various oligomers coated to a metal blade by using the described plasma enhanced chemical vapor deposition process. For these samples a tie layer is included. The tie layer and oligomer are coated separately. The tie layer was deposited using PECVD followed by the oligomer being deposited using PECVD. During deposition of the oligomer, the power was pulsed. The duty cycle (percent of the deposition time that the power was on) and frequency (Hz) are indicated in Table 3. The total time of the power off (ms) is also indicated. Table 3 shows that the cutting force can be improved by pulsing the power during deposition. A plot of the plasma off time versus the cutting force is shown below in FIG. 1. This data shows that pulsing reduces the cutting force and that the more off time of the power to the plasma, the lower the cutting force.

TABLE 3

| | | | | | Off- | | | Cutting | Cutting | |
|---|---|---|---|---|---|---|---|---|---|---|
| | | Pressure | Duty | Frequency | Time | Tie | Coating | Force | Wear | |
| Sample | Oligomer | (mTorr) | Cycle | (Hz) | (ms) | Layer | Method | (lb_{f}/in) | Test | |
| 1 | DMS-T11 | 1-5 | 80 | 100 | 2 | TMS | 2 step | 5.82 | 100-200 | cuts |
| | | | | | | | plasma | | | |
| 2 | DMS-T11 | 1-5 | 50 | 100 | 5 | TMS | 2 step | 5.03 | >300 | cuts |
| | | | | | | | plasma | | | |
| 3 | DMS-T11 | 1-5 | 80 | 10 | 20 | TMS | 2 step | 5.54 | 100-200 | cuts |
| | | | | | | | plasma | | | |
| 4 | DMS-T11 | 1-5 | 50 | 10 | 50 | TMS | 2 step | 4.27 | >300 | cuts |
| | | | | | | | plasma | | | |
| 5 | DMS-T11 | 1-5 | 50 | 10 | 50 | TMS | 2 step | 2.93 | 80 | cuts |
| | | | | | | | plasma | | | |

Table 4 below shows Cutting Force data and Cutting Wear data for oligomers coated to a metal blade. In sample 1, a tie layer applied as describe above is included on the metal blade. The oligomer is coated by using the described plasma enhanced chemical vapor deposition process. However, for both of these samples the blade was not connected to the powered electrode, but instead kept at the floating potential (potential of a floating object in the plasma) which is known to those skilled in the art to be less than 10 volts. In contrast, the potential of the blade when it is in contact with the powered electrode is several hundred volts. As can be seen, a coating of the oligomer results, but the coating is much less durable than the coatings described in Tables 2 and 3.

TABLE 4

| | | | | Cutting | |
|---|---|---|---|---|---|
| | | | | Force | Wear |
| Sample | Oligomer | Tie Layer | Method | (lb_{f}/in) | Test |
| 1 | DMS-T11 | TMS | 2 step PECVD | 6.4 | 160 cuts |
| | | | plasma | | |
| 2 | DMS-T11 | None | PECVD | 5.42 | 60 cuts |

What is claimed is:

1. A coated device comprising:
a substrate;
a plasma cross-linked coating of an oligomer having a molecular weight between 1000 and 10,000.

2. The coated device of claim 1, wherein the substrate is metal, plastic, or ceramic.

3. The coated device of claim 1, wherein the oligomer has a molecular weight between 3500 and 6000.

4. The coated device of claim 1, wherein the oligomer is selected from the group consisting of silicone-containing hydrocarbon, aromatic hydrocarbons, aliphatic hydrocarbons, fluorocarbons and fluorosilicones.

5. The coated device of claim 1, wherein the plasma cross-linked coating has a cutting force less than 5 lb_{f}/in, as defined by the cutting force test method.

6. The coated device of claim 1, wherein the plasma cross-linked coating has a cutting wear of greater than 100 cuts, as defined by the cutting wear test method.

7. The coated device of claim 1, wherein the substrate further comprises a surface treatment.

8. The coated device of claim 7, wherein the surface treatment comprises a tie layer between the metal substrate and the resin coating, ion bombardment, chemical etching, electrodischarge machining (EDM), sputter coating, or combinations thereof.

9. The coated device of claim 8, wherein the tie layer is amorphous hydrogenated silicon carbide

10. A cutting device comprising:
a substrate;
a tie layer coated on the metal substrate;
a plasma cross-linked coating of an oligomer on the tie layer, wherein the oligomer has a molecular weight between 1000 and 10,000.

11. The cutting device of claim 10, wherein the tie layer is amorphous hydrogenated silicon carbide.

12. A method of coating comprising:
providing a substrate on an electrode in a chamber;
providing a power supply to the electrode;
introducing an oligomer into the chamber;
activating the power supply to create a plasma of the oligomer within the chamber;
depositing the oligomer on the metal substrate.

13. The method of claim 12, wherein the power supply to the electrode is pulsed.

14. The method of any one of claims 12, wherein the power supply to the electrode is on less than 75% of the depositing time.

15. The method of any one of claims 12, wherein the plasma consists of the oligomer.

16. The method of any one of claims 12, wherein the substrate further comprises a surface treatment comprising a tie layer deposited onto the metal substrate, ion bombardment, chemical etching, electrodischarge machining (EDM), sputter coating, or combinations thereof.

17. A method of coating comprising:
55519 providing a substrate on an electrode in a chamber;
providing a power supply to the electrode;
introducing an oligomer into the chamber;
activating the power supply to create a plasma consisting of the oligomer within the chamber;
depositing the oligomer on the substrate.

18. The method claim 17, wherein the substrate includes a surface treatment comprising a tie layer deposited onto the metal substrate, ion bombardment, chemical etching, electrodischarge machining (EDM), sputter coating, or combinations thereof.

19. A method of coating comprising:
providing a substrate on an electrode in a chamber;
providing a power supply to the electrode;
introducing an oligomer into the chamber;
pulsing the power supply to create a plasma;
depositing the resin on the substrate.

20. The method of coating of claim 19, wherein the power supply is pulsed between on and off.

21. The method of coating of any one of claims 19, wherein the power supply to the electrode is on less than 75% of the depositing time.
